(19) United States
(12) Patent Application Publication
(10) Pub. No.: US 2026/0093869 A1
(43) Pub. Date: Apr. 2, 2026

(54) VALIDATING SELF DRIVING SIMULATORS USING AUTONOMY REALISM EVALUATION OF SIMULATION

(71) Applicant: Waabi Innovation Inc., Toronto (CA)

(72) Inventors: Raquel URTASUN, Toronto (CA); Sivabalan MANIVASAGAM, Toronto (CA); Kelvin WONG, Toronto (CA); Ioan Andrei BÂRSAN, Toronto (CA); Thang PHAM, Toronto (CA); Luisa SAN MARTIN FERREIRA, Toronto (CA); Neil Clifford ISAAC, Toronto (CA); Er Jun LI, Toronto (CA); Nicolas NASSAR, San Francisco, CA (US)

(73) Assignee: Waabi Innovation Inc., Toronto (CA)

(21) Appl. No.: 18/902,770

(22) Filed: Sep. 30, 2024

(51) Int. Cl. G06F 30/27

(52) U.S. Cl. CPC G06F 30/27

(57) ABSTRACT

A method validates autonomous system simulators using autonomy realism evaluation of simulation. The method includes receiving real-world data including real sensor data captured with a sensor system of an autonomous system. The method further includes generating a digital twin specification from the real-world data. The method further includes executing a world simulation using the digital twin specification to generate simulated world data. The method further includes processing the real-world data and the simulated world data using an evaluation model to generate a domain gap metric and a realism evaluation. The domain gap metric includes a difference measured between the real-world data and the simulated world data. The realism evaluation includes one or more of an error value from the domain gap metric, and a realism value of one or more components of the world simulation. The realism value is calculated as one minus the error value.

### BACKGROUND

To guide the development and enable the deployment in the real world of autonomous systems safely, the performance of the autonomous system is tested in an expansive set of situations that may be encountered. A popular approach has been to test in the public. For example, for autonomous systems that are self-driving vehicles (SDVs), an approach is to accumulate testing miles by driving on public roads. However, testing on public roads means that the frequency of events cannot be controlled and instead, chance is relied upon to naturally unveil the distribution across the possible set of situations. Testing in public is not scalable, and the amount of time for testing coverage would be too high as many events happen very rarely. For instance, for human driving, the rate of life-threatening injury is 1.37 incidents every 100 million miles. With real-world testing, SDV driving may be at scale to have confidence in the incident rates estimated for autonomy driven systems, which is difficult to achieve. Testing in public also carries significant exposure of risk to the public by increasing the chance of a hazardous event occurring. Furthermore, there are many situations that are difficult to test for, such as accidents or safety critical situations, which may be unethical and not safe. Moreover, for every change to the virtual driver software or hardware, the exercise of driving in the real world to evaluate the system would be performed over and over again.

An alternative is to use offline simulation to evaluate an autonomous system. The most common simulation mechanism used in the industry is open-loop log replay, where data captured in the real world by a fleet of sensing systems may be played back to evaluate the virtual driver. While the data is realistic, the virtual driver is unable to interact with the environment and actors, or to execute new actions as the data has already been captured, so the full system performance may not be understood using open-loop replays. If the autonomous system executes a new action and moves to a new location that is different from the position where the data was captured, the recorded sensor data may be inconsistent with the new location, and the positions of the other actors (vehicles, pedestrians, etc.) that may have changed based on the new position of the autonomous system, which cannot be modified as part of the open-loop replay.

Another form of simulation models the behaviors of actors to evaluate the motion planning module of the autonomy system as a “behavior” simulation. The behavior simulation controls the position of each actor, and then generates an abstraction of the actors, such as bounding boxes with future trajectories, to give as input to the motion planning module. A behavior simulation approach uses modularity and does not evaluate the effect of other components, such as perception, and the potential compounding of errors affecting performance.

Additionally, existing offline simulation systems that simulate directly from sensor inputs often use computer graphics with artist-designed assets to simulate sensor observations, resulting in limited diversity and low realism. The scenarios that may be created using scenarios of artist-designed assets are limited to the scenes and assets that have been pre-built by artists and may not necessarily correspond to real world locations or traffic layouts. Using artist-designed simulations may make an evaluation of performance in simulation that is not indicative of the real world.

Closed-loop simulation may also be used to evaluate the performance of autonomous systems, if the simulation accurately reflects how the autonomous systems would behave in the real world. A challenge with closed-loop simulation is the lack of ways to measure the fidelity of end-to-end closed-loop simulation systems. Without a way to evaluate simulation fidelity, the simulator remains solely a tool for developers to use to analyze autonomous system behavior at a coarse level, but not to validate the performance and safety of the autonomous system. A challenge is to be able to use closed-loop simulation to make a scientific safety case for the performance of autonomous systems.

### SUMMARY

In general, in one or more aspects, the disclosure relates to a method that validates autonomous system simulators using autonomy realism evaluation of simulation. The method includes receiving real-world data including real sensor data captured with a sensor system of an autonomous system. The method further includes generating a digital twin specification from the real-world data. The method further includes executing a world simulation using the digital twin specification to generate simulated world data. The method further includes processing the real-world data and the simulated world data using an evaluation model to generate a domain gap metric and a realism evaluation. The domain gap metric includes a difference measured between the real-world data and the simulated world data. The realism evaluation includes one or more of an error value from the domain gap metric, and a realism value of one or more components of the world simulation. The realism value is calculated as one minus the error value.

In general, in one or more aspects, the disclosure relates to a system that includes at least one processor and an application that executes on the at least one processor. Executing the application performs receiving real-world data including real sensor data captured with a sensor system of an autonomous system. Executing the application further performs generating a digital twin specification from the real-world data. Executing the application further performs executing a world simulation using the digital twin specification to generate simulated world data. Executing the application further performs processing the real-world data and the simulated world data using an evaluation model to generate a domain gap metric and a realism evaluation. The domain gap metric includes a difference measured between the real-world data and the simulated world data. The realism evaluation includes one or more of an error value from the domain gap metric, and a realism value of one or more components of the world simulation. The realism value is calculated as one minus the error value.

In general, in one or more aspects, the disclosure relates to a non-transitory computer readable medium including instructions executable by at least one processor. Executing the instructions performs receiving real-world data including real sensor data captured with a sensor system of an autonomous system. Executing the instructions further performs generating a digital twin specification from the real-world data. Executing the instructions further performs executing a world simulation using the digital twin specification to generate simulated world data. Executing the instructions further performs processing the real-world data and the simulated world data using an evaluation model to generate a domain gap metric and a realism evaluation. The domain gap metric includes a difference measured between the real-world data and the simulated world data. The realism evaluation includes one or more of an error value from the domain gap metric, and a realism value of one or more components of the world simulation. The realism value is calculated as one minus the error value.

Other aspects of one or more embodiments may be apparent from the following description and the appended claims.

### BRIEF DESCRIPTION OF DRAWINGS

FIG. 1 shows a diagram of an autonomous training and testing system in accordance with the disclosure.

FIG. 2 shows a flowchart of the autonomous training and testing system in accordance with the disclosure.

FIG. 3 shows a flow diagram in accordance with the disclosure.

FIG. 4 shows a method in accordance with the disclosure.

FIG. 5, FIG. 6A, FIG. 6B, FIG. 7A, FIG. 7B, FIG. 8A, FIG. 8B, FIG. 9A, FIG. 9B, FIG. 10, and FIG. 11, show examples in accordance with the disclosure.

FIG. 12A and FIG. 12B show a computing system in accordance with the disclosure.

Similar elements in the various figures may be denoted by similar names and reference numerals. The features and elements described in one figure may extend to similarly named features and elements in different figures.

### DETAILED DESCRIPTION

Embodiments of the disclosure validate self-driving simulators using autonomy realism evaluation of simulation by measuring the realism of a simulator for self-driving. Embodiments of the disclosure use a “paired-scenario” setting, where a digital twin is recreated in simulation of the same scenario that the autonomy system observed when driving in the real world. The digital twin occurs on the same map, with the same traffic participant (actor) placement and routes as observed in the real world. The virtual driver may then run in closed-loop simulation with a simulator that controls the actors reactively, models the autonomous systems dynamics, and simulates new sensor observations, to analyze the actions of the virtual driver. By analyzing the simulation result, whether the virtual driver perceived and reacted to other actors the same way in simulation as in the real world for the same scenario may be evaluated.

Embodiments of the disclosure may directly measure the realism of the simulation system and the components thereof. The realism of the simulation system may be evaluated on any scenario that the virtual driver encountered and drove in the real world, enabling realism evaluation at scale on a wide variety of scenarios that cover the operating domain of the autonomous system. Some of the improvements to autonomous system technology within the disclosure include: (1) a framework to build modifiable digital twins of real scenarios observed by the autonomous system, (2) the ability to execute these paired digital twin scenarios as simulations to evaluate the autonomy system in closed loop, (3) a system to measure and evaluate realism metrics in this paired-scenario setting, etc.

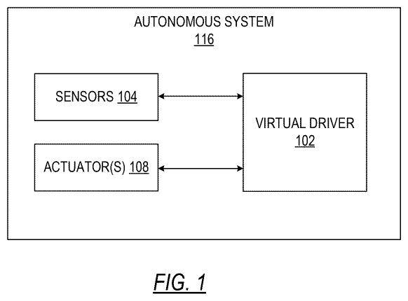

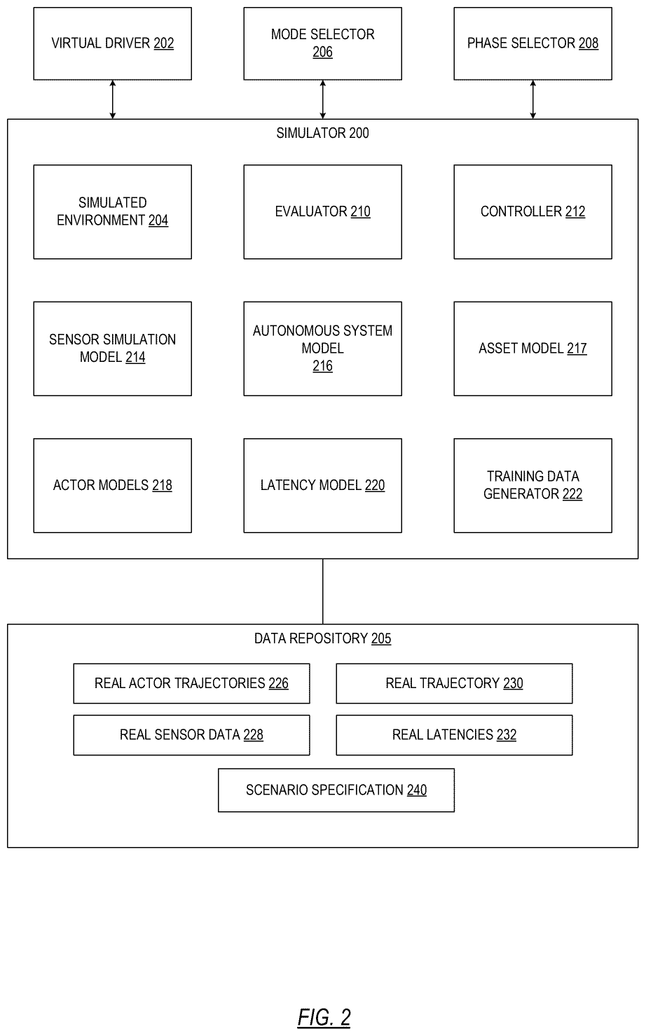

Turning to the Figures, FIG. 1 and FIG. 2 show example diagrams of the autonomous system and virtual driver that may embody the disclosure. Turning to FIG. 1, an autonomous system (116) is a self-driving mode of transportation that does not require a human pilot or human driver to move and react to the real-world environment. The autonomous system (116) may be completely autonomous or semi-autonomous. As a mode of transportation, the autonomous system (116) is contained in a housing configured to move through a real-world environment. Examples of autonomous systems include self-driving vehicles (e.g., self-driving trucks and cars), drones, airplanes, robots, etc.

The autonomous system (116) includes a virtual driver (102) that is the decision-making portion of the autonomous system (116). The virtual driver (102) is an artificial intelligence system that learns how to interact in the real world and interacts accordingly. The virtual driver (102) is the software executing on a processor that makes decisions and causes the autonomous system (116) to interact with the real world including moving, signaling, and stopping, or maintaining a current state. Specifically, the virtual driver (102) is decision making software that executes on hardware (not shown). The hardware may include a hardware processor, memory or other storage device, and one or more interfaces. A hardware processor is any hardware processing unit that is configured to process computer readable program code and perform the operations set forth in the computer readable program code.

A real-world environment is the portion of the real world through which the autonomous system (116), when trained, is designed to move. Thus, the real-world environment may include concrete and land, construction, and other objects in a geographic region along with agents. The agents are the other agents in the real-world environment that are capable of moving through the real world environment. Agents may have independent decision-making functionality. The independent decision-making functionality of the agent may dictate how the agent moves through the environment and may be based on visual or tactile cues from the real-world environment. For example, agents may include other autonomous and non-autonomous transportation systems (e.g., other vehicles, bicyclists, robots), pedestrians, animals, etc.

In the real world, the geographic region is an actual region within the real world that surrounds the autonomous system. Namely, from the perspective of the virtual driver, the geographic region is the region through which the autonomous system moves. The geographic region includes agents and map elements that are located in the real world. Namely, the agents and map elements each have a physical location in the geographic region that denotes a place in which the corresponding agent or map element is located. The map elements are stationary in the geographic region, whereas the agents may be stationary or nonstationary in the geographic region. The map elements are the elements shown in a map (e.g., road map, traffic map, etc.) or derived from a map of the geographic region.

The real-world environment changes as the autonomous system (116) moves through the real-world environment. For example, the geographic region may change, and the agents may move positions, including new agents being added and existing agents leaving.

In order to interact with the real-world environment, the autonomous system (116) includes various types of sensors (104), such as LiDAR sensors, amongst other types, which are used to obtain measurements of the real-world environment, and cameras that capture images from the real world environment. The autonomous system (116) may include other types of sensors as well. The sensors (104) provide input to the virtual driver (102).

In addition to sensors (104), the autonomous system (116) includes one or more actuators (108). An actuator is hardware and/or software that is configured to control one or more physical parts of the autonomous system based on a control signal from the virtual driver (102). In one or more embodiments, the control signal specifies an action for the autonomous system (e.g., turn on the blinker, apply brakes by a defined amount, apply accelerator by a defined amount, turn the steering wheel or tires by a defined amount, etc.). The actuator(s) (108) are configured to implement the action. In one or more embodiments, the control signal may specify a new state of the autonomous system (116) and the actuator (108) may be configured to implement the new state to cause the autonomous system (116) to be in the new state. For example, the control signal may specify that the autonomous system (116) should turn by a certain amount while accelerating at a predefined rate, while the actuator (108) determines and causes the wheel movements and the amount of acceleration on the accelerator to achieve a certain amount of turn and acceleration rate.

The testing and training of a virtual driver of the autonomous systems in the real-world environment is unsafe because of the accidents that an untrained virtual driver can cause. Thus, as shown in FIG. 2, a simulator (200) is configured to train and test a virtual driver (202) of an autonomous system. Once trained, the virtual driver (202) may be deployed to a real-world system, such as the autonomous system (116) of FIG. 1.

The simulator (200) may be a unified, modular, mixed reality, closed-loop simulator for autonomous systems. The simulator (200) is a configurable simulation framework that enables not only evaluation of different autonomy components in isolation, but also as a complete system in a closed-loop manner. The simulator (200) reconstructs “digital twins” of real-world scenarios automatically, enabling accurate evaluation of the virtual driver (202) at scale. The simulator (200) may also be configured to perform mixed reality simulation that combines real-world data and simulated data to create diverse and realistic evaluation variations to provide insight into the virtual driver's (202) performance. The mixed reality closed-loop simulation allows the simulator (200) to analyze the virtual driver's (202) action on counterfactual “what-if” scenarios that did not occur in the real world. The simulator (200) further includes functionality to simulate and train on rare yet safety-critical scenarios with respect to the entire autonomous system and closed loop training to enable automatic and scalable improvement of autonomy.

The simulator (200) creates the simulated environment (204) that is a virtual world in which the virtual driver (202) is the player in the virtual world. The simulated environment (204) is a simulation of a real-world environment, which may or may not be in actual existence, in which the autonomous system is designed to move. As such, the simulated environment (204) includes a simulation of the objects (i.e., simulated objects or assets) and background in the real world, including the natural objects, construction, buildings and roads, obstacles, as well as other autonomous and non-autonomous objects. The simulated environment (204) simulates the environmental conditions within which the autonomous system may be deployed. Additionally, the simulated environment (204) may be configured to simulate various weather conditions that may affect the inputs to the autonomous systems. The simulated objects may include both stationary and non-stationary objects. Non-stationary objects are actors in the real-world environment.

The simulator (200) also includes an evaluator (210). The evaluator (210) is configured to train and test the virtual driver (202) by creating various scenarios in the simulated environment (204). Each scenario is a configuration of the simulated environment (204) including, but not limited to, static portions, movement of simulated objects, actions of the simulated objects with each other, and reactions to actions taken by the autonomous system and simulated objects. The evaluator (210) is further configured to evaluate the performance of the virtual driver (202) using a variety of metrics.

The evaluator (210) assesses the performance of the virtual driver (202) throughout the performance of the scenario. Assessing the performance may include applying rules. For example, the rules may be that the automated system does not collide with any other actor, compliance with safety and comfort standards (e.g., passengers not experiencing more than a certain acceleration force within the vehicle), the automated system not deviating from an executed trajectory, or other rule. Each rule may be associated with the metric information that relates a degree of breaking the rule with a corresponding score. The evaluator (210) may be implemented as a data-driven neural network that learns to distinguish between good and bad driving behavior. The various metrics of the evaluation system may be leveraged to determine whether the automated system satisfies the requirements of success criterion for a particular scenario. Further, in addition to system level performance, for modular based virtual drivers, the evaluator (210) may also evaluate individual modules such as segmentation or prediction performance for actors in the scene with respect to the ground truth recorded in the simulator (200).

The simulator (200) is configured to operate in multiple phases as selected by the phase selector (208) and modes as selected by a mode selector (206). The phase selector (208) and mode selector (206) may be a graphical user interface or application programming interface component that is configured to receive a selection of phase and mode, respectively. The selected phase and mode define the configuration of the simulator (200). Namely, the selected phase and mode define which system components communicate and the operations of the system components.

The phase may be selected using a phase selector (208). The phase may be a training phase or a testing phase. In the training phase, the evaluator (210) provides metric information to the virtual driver (202), which uses the metric information to update the virtual driver (202). The evaluator (210) may further use the metric information to further train the virtual driver (202) by generating scenarios for the virtual driver (202). In the testing phase, the evaluator (210) does not provide the metric information to the virtual driver (202). In the testing phase, the evaluator (210) uses the metric information to assess the virtual driver (202) and to develop scenarios for the virtual driver (202).

The mode may be selected by the mode selector (206). The mode defines the degree to which real-world data is used, whether noise is injected into simulated data, degree of perturbations of real-world data, and whether the scenarios are designed to be adversarial. Example modes include open-loop simulation mode, closed-loop simulation mode, single module closed-loop simulation mode, fuzzy mode, and adversarial mode. In an open-loop simulation mode, the virtual driver (202) is evaluated with real-world data. In a single module closed-loop simulation mode, a single module of the virtual driver (202) is tested. An example of a single module closed-loop simulation mode is a localizer closed-loop simulation mode in which the simulator (200) evaluates how the localizer estimated pose drifts over time as the scenario progresses in simulation. In a training data simulation mode, the simulator (200) is used to generate training data. In a closed-loop evaluation mode, the virtual driver (202) and simulation system are executed together to evaluate system performance. In the adversarial mode, the actors are modified to perform adversarial to each other. In the fuzzy mode, noise is injected into the scenario (e.g., to replicate signal processing noise and other types of noise). Other modes may exist without departing from the scope of the system.

The simulator (200) includes the controller (212) that includes functionality to configure the various components of the simulator (200) according to the selected mode and phase. Namely, the controller (212) may modify the configuration of each of the components of the simulator (200) based on configuration parameters of the simulator (200). Such components include the evaluator (210), the simulated environment (204), an autonomous system model (216), sensor simulation models (214), asset models (217), actor models (218), latency models (220), and a training data generator (222).

The autonomous system model (216) is a detailed model of the autonomous system in which the virtual driver (202) will execute. The autonomous system model (216) includes model, geometry, physical parameters (e.g., mass distribution, points of significance), engine parameters, sensor locations and type, firing pattern of the sensors, information about the hardware on which the virtual driver (202) executes (e.g., processor power, amount of memory, and other hardware information), and other information about the autonomous system. The various parameters of the autonomous system model (216) may be configurable by the user or another system.

For example, if the autonomous system is a motor vehicle, the modeling and dynamics may include the type of vehicle (e.g., car, truck), make and model, geometry, physical parameters such as the mass distribution, axle positions, type and performance of engine, etc. The vehicle model may also include information about the sensors on the vehicle (e.g., camera, LiDAR, etc.), the sensors' relative firing synchronization pattern, and the sensors' calibrated extrinsics (e.g., position and orientation), and intrinsics (e.g., focal length). The vehicle model also defines the onboard computer hardware, sensor drivers, controllers, and the autonomy software release under test.

The autonomous system model (216) includes an autonomous system dynamic model. The autonomous system dynamic model is used for dynamics simulation that takes the actuation actions of the virtual driver (202) (e.g., steering angle, desired acceleration) and enacts the actuation actions on the autonomous system in the simulated environment (204) to update the simulated environment (204) and the state of the autonomous system. To update the state, a kinematic motion model may be used, or a dynamics motion model that accounts for the forces applied to the vehicle may be used to determine the state. Within the simulator (200), with access to real log scenarios with ground truth actuations and vehicle states at each time step, embodiments may also optimize analytical vehicle model parameters or learn parameters of a neural network that infers the new state of the autonomous system given the virtual driver (202) outputs.

In one or more embodiments, the sensor simulation model (214) models, in the simulated environment (204), active and passive sensor inputs. Passive sensor inputs capture the visual appearance of the simulated environment (204) including stationary and nonstationary simulated objects from the perspective of one or more cameras based on the simulated position of the camera(s) within the simulated environment (204). Examples of passive sensor inputs include inertial measurement unit (IMU) and thermal. Active sensor inputs are inputs to the virtual driver (202) of the autonomous system from the active sensors, such as LiDAR, RADAR, global positioning system (GPS), ultrasound, etc. Namely, the active sensor inputs include the measurements taken by the sensors, the measurements being simulated based on the simulated environment (204) based on the simulated position of the sensor(s) within the simulated environment (204). By way of an example, the active sensor measurements may be measurements that a LiDAR sensor would make of the simulated environment (204) over time and in relation to the movement of the autonomous system.

The sensor simulation models (214) are configured to simulate the sensor observations of the surrounding scene in the simulated environment (204) at each time step according to the sensor configuration on the vehicle platform. When the simulated environment (204) directly represents the real-world environment, without modification, the sensor output may be directly fed into the virtual driver (202). For light-based sensors, the sensor model simulates light as rays that interact with objects in the scene to generate the sensor data. Depending on the asset representation (e.g., of stationary and nonstationary objects), embodiments may use graphics-based rendering for assets with textured meshes, neural rendering, or a combination of multiple rendering schemes. Leveraging multiple rendering schemes enables customizable world building with improved realism. Because assets are compositional in 3D and support a standard interface of render commands, different asset representations may be composed in a seamless manner to generate the final sensor data. Additionally, for scenarios that replay what happened in the real world and use the same autonomous system as in the real world, the original sensor observations may be replayed at each time step.

Asset models (217) include multiple models, each model modeling a particular type of individual asset from the real world. The assets may include inanimate objects such as construction barriers, traffic signs, parked cars, and background (e.g., vegetation or sky). Each of the entities in a scenario may correspond to an individual asset. As such, an asset model (217), or instance of a type of asset model (217), may exist for each of the entities or assets in the scenario. The assets can be composed together to form the three-dimensional simulated environment. An asset model provides all the information needed by the simulator (200) to simulate the asset. The asset model (217) provides the information used by the simulator (200) to represent and simulate the asset in the simulated environment (204). For example, an asset model (217) may include geometry and bounding volume, the asset's interaction with light at various wavelengths of interest (e.g., visible for camera, infrared for LiDAR, microwave for RADAR), animation information describing deformation (e.g., rigging) or lighting changes (e.g., turn signals), material information such as friction for different surfaces, and metadata such as the asset's semantic class and key points of interest. Certain components of the asset may have different instantiations. For example, similar to rendering engines, an asset geometry may be defined in many ways, such as a mesh, voxels, point clouds, an analytical signed distance function, or neural network. Asset models (217) may be created either by artists, or reconstructed from real world sensor data, or optimized by an algorithm to be adversarial.

Closely related to, and possibly considered part of the set of asset models (217), are actor models (218). An actor model (218) represents an actor in a scenario. An actor is a sentient being that has an independent decision-making process. Namely, in a real world, the actor may be an animate being (e.g., person or animal) that makes a decision based on an environment. The actor makes active movement rather than, or in addition to, passive movement. An actor model, or an instance of an actor model may exist for each actor in a scenario. The actor model (218) is a model of the actor. If the actor is in a mode of transportation, then the actor model (218) includes the mode of transportation in which the actor is located. For example, the actor models (218) may represent pedestrians, children, vehicles being driven by drivers, pets, bicycles, and other types of actors.

The actor model (218) leverages the scenario specification and assets to control all actors in the scene and their actions at each time step. The actor's behavior is modeled in a region of interest centered around the autonomous system. Depending on the scenario specification, the actor simulation will control the actors in the simulation to achieve the desired behavior. Actors can be controlled in various ways. One option is to leverage heuristic actor models, such as an intelligent-driver model (IDM) that may try to maintain a certain relative distance or time-to-collision (TTC) from a lead actor or heuristic-derived lane-change actor models. Another is to directly replay actor trajectories from a real log, or to control the actor(s) with a data-driven traffic model. Through the configurable design, embodiments may mix and match different subsets of actors to be controlled by different behavior models. For example, far-away actors that initially may not interact with the autonomous system and can follow a real log trajectory, but when near the vicinity of the autonomous system may switch to a data-driven actor model. In another example, actors may be controlled by a heuristic or data-driven actor model that still conforms to the high-level route in a real log. This mixed reality simulation provides control and realism.

Further, actor models (218) may be configured to be in cooperative or adversarial mode. In cooperative mode, the actor model (218) models actors to act rationally in response to the state of the simulated environment (204). In adversarial mode, the actor model (218) may model actors acting irrationally, such as exhibiting road rage, bad driving, etc.

The latency model (220) represents timing latency that occurs when the autonomous system is in the real-world environment. Several sources of timing latency may exist. For example, a latency may exist from the time that an event occurs to the sensors detecting the sensor information from the event and sending the sensor information to the virtual driver (202). Another latency may exist based on the difference between the computing hardware executing the virtual driver (202) in the simulated environment (204) as compared to the computing hardware of the virtual driver (202). Further, another timing latency may exist between the time that the virtual driver (202) transmits an actuation signal to the autonomous system changing (e.g., direction or speed) based on the actuation signal. The latency model (220) models the various sources of timing latency.

Stated another way, in the real world, safety-critical decisions in the real world may involve fractions of a second affecting response time. The latency model (220) simulates the exact timings and latency of different components of the onboard system. To enable a scalable evaluation without a strict requirement on exact hardware, the latencies and timings of the different components of autonomous system and sensor modules are modeled while running on different computer hardware. The latency model (220) may replay latencies recorded from previously collected real-world data or have a data-driven neural network that infers latencies at each time step to match the hardware in loop simulation setup.

The training data generator (222) is configured to generate training data. For example, the training data generator (222) may modify real world scenarios to create new scenarios. The modification of real-world scenarios is referred to as mixed reality. For example, mixed reality simulation may involve adding in new actors with novel behaviors, changing the behavior of one or more of the actors from the real world, and modifying the sensor data in that region while keeping the remainder of the sensor data the same as the original log. In some cases, the training data generator (222) converts a benign scenario into a safety-critical scenario.

The simulator (200) is connected to a data repository (205). The data repository (205) is any type of storage unit or device that is configured to store data. The data repository (205) includes data gathered or derived from the real world and may be referred to as real-world data. For example, the data gathered from the real world includes real actor trajectories (226), real sensor data (228), real trajectory of the system capturing the real world (230), and real latencies (232). Each of the real actor trajectories (226), real sensor data (228), real trajectory of the system capturing the real world (230), and real latencies (232) is data captured by or calculated directly from one or more sensors from the real world (e.g., in a real-world log). In other words, the data gathered from the real world are actual events that happened in real life. For example, in the case that the autonomous system is a vehicle, the real-world data may be captured by a vehicle driving in the real world with sensor equipment.

Further, the data repository (205) includes functionality to store one or more scenario specifications (240). A scenario specification (240) specifies a scenario and evaluation setting for testing or training the autonomous system. For example, the scenario specification (240) may describe the initial state of the scene, such as the current state of the autonomous system (e.g., the full 6D pose, velocity, and acceleration), the map information specifying the road layout, and the scene layout specifying the initial state of all the dynamic actors and objects in the scenario. The scenario specification may also include dynamic actor information describing how the dynamic actors in the scenario should evolve over time, which are inputs to the actor models (218). The dynamic actor information may include route information for the actors, desired behaviors, or aggressiveness. The scenario specification (240) may be specified by a user, programmatically generated using a domain specification language (DSL), procedurally generated with heuristics from a data-driven algorithm, or adversarial. The scenario specification (240) can also be conditioned on data collected from a real-world log, such as taking place on a specific real world map or having a subset of actors defined by their original locations and trajectories.

The interfaces between virtual driver (202) and the simulator (200) may match the interfaces between the virtual driver (202) and the autonomous system in the real world. For example, the sensor simulation model (214) and the virtual driver (202) matches the virtual driver (202) interacting with the sensors in the real world. The virtual driver (202) is the actual autonomy software that executes on the autonomous system. The simulated sensor data that is output by the sensor simulation model (214) may be in or converted to the exact message format that the virtual driver (202) takes as input as if the virtual driver (202) were in the real world, and the virtual driver (202) can then run as a black box virtual driver with the simulated latencies incorporated for components that run sequentially. The virtual driver (202) then outputs the exact same control representation that it uses to interface with the low-level controller on the real autonomous system. The autonomous system model (216) will then update the state of the autonomous system in the simulated environment (204). Thus, the various simulation models of the simulator (200) run in parallel asynchronously at their own frequencies to match the real-world setting.

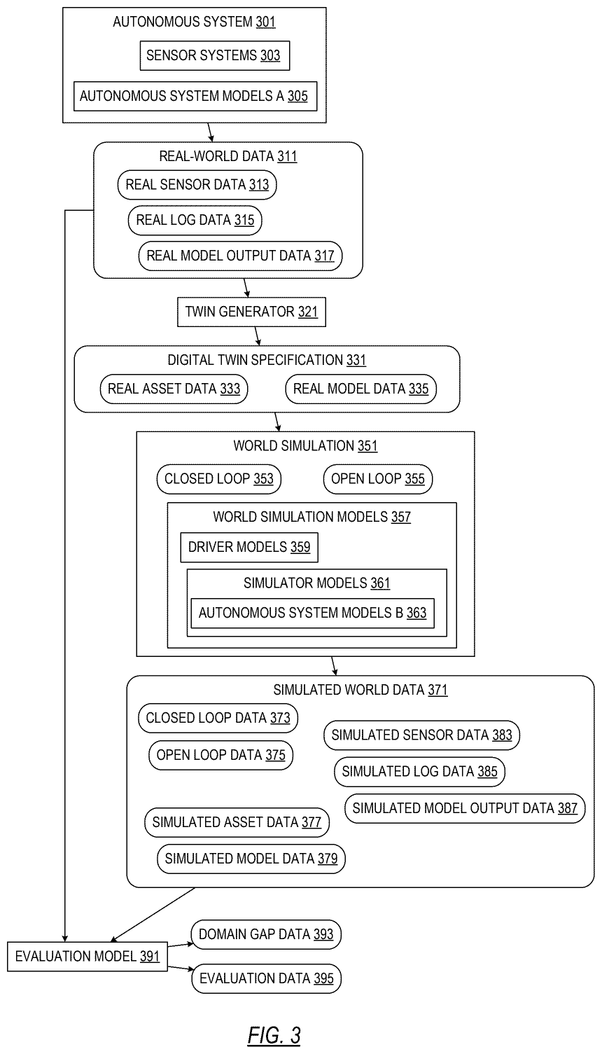

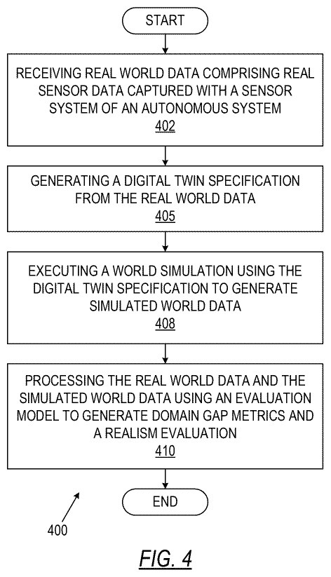

Turning to FIG. 3, systems and applications process data to validate self-driving simulators using an autonomy realism evaluation of simulation. For example, the realism of the world simulation (351) is tested with the evaluation model (391) in the real-world data (311) captured with the autonomous system (301).

The autonomous system (301) may implement the autonomous system (116) of FIG. 1. The autonomous system (301) captures data using the sensor systems (303) and processes data (including the captured data) with the autonomous system models A (305) to generate the real-world data (311).

The sensor systems (303) may include implementations of the sensors (104) of FIG. 1. The sensor systems (303) capture data and may perform initial processing on the captured data to generate the real sensor data (313) and the real log data (315).

The autonomous system models A (305) include computational models (including machine learning models) that may process the data from the sensor systems (303) to generate the real model output data (317). The autonomous system models A (305) may implement components of the virtual driver (102) of FIG. 1.

The real-world data (311) is data generated by the autonomous system (301). The real-world data (311) may be generated by multiple autonomous systems (e.g., from multiple vehicles), including the autonomous system (301). The real-world data (311) includes the real sensor data (313), the real log data (315), and the real model output data (317). The real-world data (311) may be used as inputs to the twin generator (321) and to the evaluation model (391).

The real sensor data (313) is data output from the sensor systems (303) of the autonomous system (301). The real sensor data (313) may include data from camera sensors, LiDAR sensors, etc., that measure the real-world environment of the autonomous system (301).

The real log data (315) is data generated with the autonomous system (301). The real log data (315) may include logs of events detected by the autonomous system (301).

The real model output data (317) is data generated by the autonomous system models A (305). The real model output data (317) includes the outputs from the autonomous system models A (305) generated in response to processing one or more of the real sensor data (313) and the real log data (315).

The twin generator (321) may be an application that processes the real-world data (311). The twin generator (321) processes the real-world data (311) to generate the digital twin specification (331).

The digital twin specification (331) is the output from the twin generator (321) that is used by the world simulation (351) to generate the simulated world data (371), which may form a mirror or be a twin of the real-world data (311). The digital twin specification (331) includes the real asset data (333) and the real model data (335). A comparison of the digital twin specification (331) with other digital twin specifications may indicate the types of scenarios for which the world simulation (351) is realistic. For example, sunny days but not snowy days, vehicles and pedestrians, but not animals like birds. New digital twin specifications may be made from the digital twin specification (331) and have similar realism to the digital twin specification (331) (as measured by the domain gap data (393) and the evaluation data (395)) and be used for evaluation and training of the autonomy driver models. used by the system.

The digital twin specification (331) may represent a scenario. A scenario is the collection of one or more events traversed by an autonomous system. For example, a merge scenario may include the events and corresponding data for the autonomous system to operate the vehicle to merge into another lane. The events and data of a trip made by a vehicle may be split into multiple scenarios. Each scenario may focus on a real event (lane change, merge, turn, etc.). For each scenario, the corresponding digital twin specification (331) includes a record of all the detected vehicles, locations, map positions, etc., from the start to the finish of the scenario.

The real asset data (333) is data of assets that may be part of the world simulation (351). The assets may include three dimensional models, meshes, textures, etc., of objects in a scene (including cars, pedestrians, trees, etc.) as well as locations, trajectories, velocities, accelerations, etc., for the objects. The real asset data (333) may be used by the world simulation (351) to generate the simulated asset data (377) as well as one or more of the simulated sensor data (383), the simulated log data (385), the simulated model output data (387).

The real model data (335) is data for the world simulation models (357) of the world simulation (351). The real model data (335) may be used by the world simulation models (357) to generate the simulated model data (379) as well as one or more of the simulated sensor data (383), the simulated log data (385), and the simulated model output data (387).

The world simulation (351) may be a collection of computer programs operating as an application to process the digital twin specification (331) and generate the simulated world data (371). The world simulation (351) may be a virtual world simulation that may operate in closed loop (353) or in open loop (355) and may include the world simulation models (357).

The closed loop (353) is an identifier for the world simulation (351). When the world simulation (351) operates in the closed loop (353), the systems and models being simulated may behave dynamically in response to the decisions made by the systems and models being simulated. For example, a virtual driver may perform a maneuver that was not part of the real-world data (311) and each of the other objects within the simulation may respond to the maneuver of the virtual driver so that the locations, actions, behaviors, etc. of the actors, vehicles, etc., recorded in the simulated world data (371) may differ from that recorded in the real-world data (311).

The open loop (355) is an identifier for the world simulation (351). When the world simulation (351) operates in the open loop (355), the systems and models being simulated do not diverge from what was recorded with the real-world data (311). In the open loop (355), the world simulation (351) may replay or playback the real-world data (311).

The world simulation models (357) are computer implemented models that calculate the simulated world data (371) using information from the district twin specification (331). The world simulation models (357) include the driver models (359) and the simulator models (361). The world simulation models (357) may include a latency model that predicts the latency between actions performed by an autonomous system and changes to the vehicle, such as changes to the velocity, trajectory, acceleration, etc., of the vehicle.

The driver models (359) are computer implemented models that may model and predict assets (e.g., other vehicles) within the world simulation (351). The driver models (359) may model behavior for different agent types including pedestrians, animals, construction workers, etc. Any agent may be controlled by a behavior model. The driver models (359) process information from the real-world data (311) to generate the simulated asset data (377) and the simulated model data (379).

The simulator models (361) are computer models that may model and predict the behaviors of the objects within the simulation. The simulator models (361) process information from the real-world data (311) to generate the simulated sensor data (383), the simulated log data (385), and the simulated model outputs data (387). The simulator models (361) may include the autonomous system models B (363).

The autonomous system models B (363) are computer implemented models that may be used by autonomous systems and are simulated within the world simulation (351). The autonomous system models B (363) correspond with the autonomous system models A (305) of the autonomous system (301) and may be the same as the autonomous system models A (305). The autonomous system models B (363) process information from the digital twin specification (331) to generate the simulated model output data (387).

The simulated world data (371) is information stored in memory generated by the world simulation (351) using the digital performance specification (331) and the real-world data (311). The simulated world data (371) includes the closed-loop data (373), the open-loop data (375), the simulated asset data (377), the simulated model data (379), the simulated sensor data (383), the simulated log data (385), and the simulated model output data (387). The simulated world data (371) is output from the world simulation (351) and input to the evaluation model (391).

The closed-loop data (373) is the set of data within the simulated world data (371), that is generated when the world simulation (351) is operated in the closed loop (353). The closed-loop data (373) may include portions of the simulated asset data (377), the simulated model data (379), the simulated sensor data (383), the simulated log data (385), and the simulated model output data (387).

The open-loop data (375) is the set of data within the simulated world data (371), that is generated when the world simulation (351) is operated in the open loop (355). The open loop data (375) may include portions of the simulated asset data (377), the simulated model data (379), the simulated sensor data (383), the simulated log data (385), and the simulated model output data (387).

The simulated asset data (377) is data describing the assets in the world simulation (351). The simulated asset data (377) may be generated from the real asset data (333).

The simulated model data (379) is data that may be the inputs and outputs of the driver models (359). The simulated model data (379) may be generated from the real model data (335).

The simulated sensor data (383) is sensor data generated from the world simulation (351). The simulated sensor data (383) may be a simulated version of the real sensor data (313).

The simulated log data (385) is log data generated from the world simulation (351). The simulated log data (385) may be a simulated version of the real log data (315).

The simulated model output data (387) may be the outputs from the autonomous system models B (363). The simulated model output data (387) may be a simulated version of the real model output data (317), which was generated by the autonomous system models A (305).

The evaluation model (391) is computer implemented model that processes the real-world data (311) and the simulated world data (371). The evaluation model (391) processes the real-world data (311) and the simulated world data (371) to generate the domain gap data (393) and the evaluation data (395).

The domain gap data (393) is data that identifies the domain gap between the simulation of a scenario generated with the world simulation (351) and the real world scenario recorded by the autonomous system (301) to the real-world data (311). The domain gap data (393) may include metrics that identify differences between the simulated world data (371), the digital twin specification (331), and the real-world data (311). The metrics may include detection agreement, displacement error, displacement error, along track error cross track error, etc.

The evaluation data (395) is data that identifies a realism evaluation for the world simulation (351) and the components thereof. The evaluation data (395) may be a subset of the domain gap data (393). The evaluation data (395) may be calculated as part of the domain gap data (393) and may include confidence values for the different models used by the world simulation (351) as well as confidence values for sets of digital twin specifications that have a high correspondence between the simulated data and real data for the digital twin specifications. A realism evaluation may include one or more numerical values that include a sensor simulation evaluation that numerically quantifies the realism of a simulation of a sensor system. The realism evaluation may also include an agreement value between the real-world data (311) and the simulated world data (371) that quantifies the similarity of the real-world data (311) to the simulated world data (371). Similarity algorithms that may be used include cosine similarity, Jaccard similarity, Levenshtein distance, etc.

Although described within the context of multiple applications that may execute on multiple computing systems, aspects of the disclosure may be practiced with a single computing system and application. For example, a monolithic application may operate on a computing system to perform the same functions as one or more of the applications executed by the autonomous system (116) and the computing system (1200).

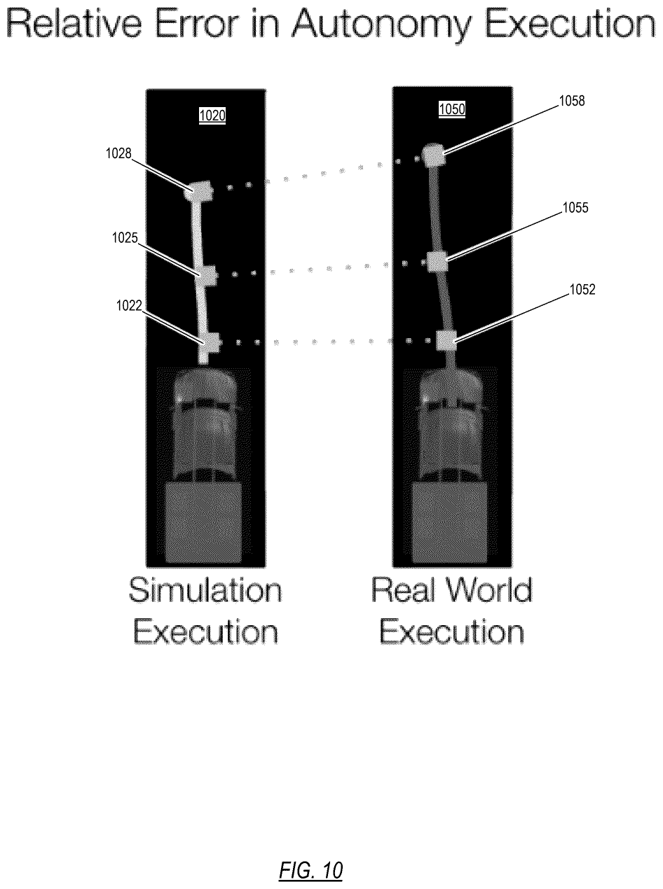

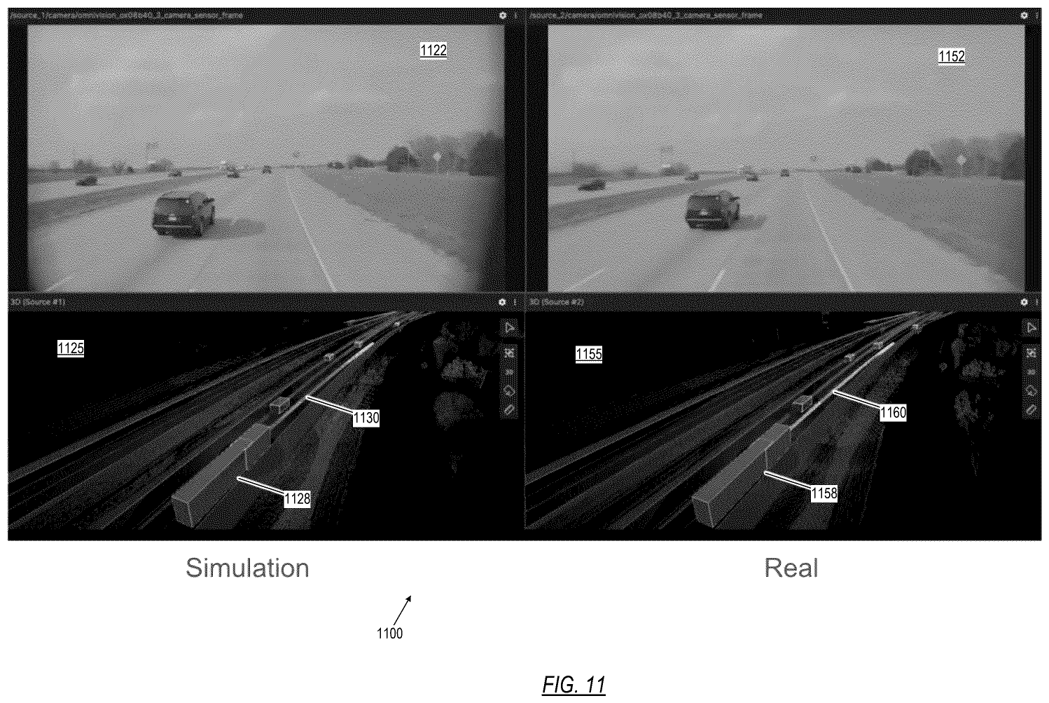

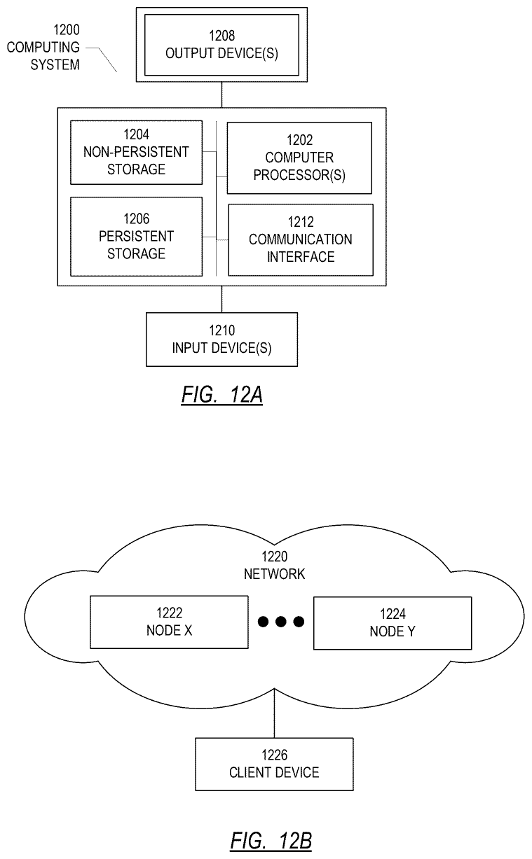

FIG. 4 shows a flowchart of a method that may implement the validation of self-driving simulators using autonomy realism evaluation of simulation. The method of FIG. 4 may be implemented using the systems and components of FIG. 1 through FIG. 3, FIG. 12A, and FIG. 12B. One or more of the steps of the method may be performed on, or received at, one or more computer processors. In an embodiment, a system may include at least one processor and an application that, when executing on the at least one processor, performs the method. In an embodiment, a non-transitory computer readable medium may include instructions that, when executed by one or more processors, perform the method. The outputs from various components (including models, functions, procedures, programs, processors, etc.) from performing the method may be generated by applying a transformation to inputs using the components to create the outputs without using mental processes or human activities.

Block (402) includes receiving real-world data including real sensor data captured with a sensor system of an autonomous system. The real-world data may be received from a database that stores real-world data from multiple autonomous systems. Receiving real-world data may include recording real logs and real model output as part of the real-world data.

Block (405) includes generating a digital twin specification from the real-world data. Generating the digital twin specification may include executing a twin generator using the real-world data to generate real asset data and real model data as part of the digital twin specification. The real asset data may be generated by identifying the detected locations of objects (including vehicles, pedestrians, signs, trees, etc.) from the real-world data, including from the real sensor data, the real log data, and the real model output data that are related to identifying the detected locations of objects. Camera data and LiDAR data may be used to generate three dimensional meshes for the objects in the camera data and may be used to generate textures for the objects. The real model data may include inferences, predictions, classifications, etc., that may be made by the models of an autonomous system.

Block (408) includes executing a world simulation using the digital twin specification to generate simulated world data. Execution of the world simulation may be done in open loop or in closed loop to generate simulated world data. Open-loop execution may effectively be a replay of the real-world data without diverging from the real-world data. Closed-loop execution may be initiated with a first time step from the real-world data but may then diverge from the real-world data based on different decisions made by the actors in the scene as generated by the models of the world simulation.

Executing the world simulation may include executing the world simulation in closed loop using an autonomous system model. The autonomous system model may make decisions and take actions that are different from the autonomous system model that operates within the autonomous system that generated the real-world data. For domain gap realism evaluation, the autonomy system models may be the same, and differences may arise due to differences between the autonomy system model being operated in simulation instead of in the real world. A different autonomy system model may run on a scenario in simulation, which may be used to understand and measure performance of the autonomy system model instead of measuring realism of the world simulation.

Executing the world simulation may include executing the world simulation in open loop using the real-world data with a latency model to generate simulated latency times as part of the simulated world data. Output from the latency model may be fed back into other models to affect the decisions and actions made to operate the autonomous system.

Block (410) includes processing the real-world data and the simulated world data using an evaluation model to generate domain gap metrics and a realism evaluation. The evaluation model may include one or more computer implemented models, which may utilize machine learning algorithms to generate domain gap data and evaluation data that includes the domain gap metrics and the realism evaluation. A domain gap metric may include differences measured between the real-world data and the simulated world data. The realism evaluation may include one or more of an error value from the domain gap metric and a realism value of one or more components of the world simulation. The realism value may be calculated as one minus the error value.

Processing the real-world data and the simulated world data to generate the domain gap metrics and the realism evaluation may include executing the world simulation in open loop using an autonomous system model with the real sensor data to generate first simulated model output from the real sensor data. Executing the world simulation in open loop using an autonomous system model with the real sensor data may not be needed when autonomy system model that operated in the real world and the autonomy system operating in simulation are the same, e.g., the real model output data (e.g., the real model output data (317) of FIG. 3) may be used. Processing the real-world data and the simulated world data to generate the domain gap metrics and the realism evaluation may include executing the world simulation in open loop using the autonomous system model with simulated sensor data to generate a second simulated model output from the simulated sensor data. Processing the real-world data and the simulated world data to generate the domain gap metrics and the realism evaluation may include executing the evaluation model using the first simulated model output and the second simulated model output to generate a sensor simulation evaluation as part of the realism evaluation. The sensor simulation evaluation may be used to revise and retrain models that generate simulated sensor data. For example, if the sensor simulation evaluation satisfies a threshold, then one or more sensor simulation models may be retrained.

Processing the real-world data and the simulated world data to generate the domain gap metrics and the realism evaluation may include executing the evaluation model using simulated behavior model output to generate behavior model metrics as part of the domain gap metrics and a behavior model evaluation as part of the realism evaluation for a behavior model. The behavior model evaluation may be used to revise and retrain models that identify the behaviors of the actors in a world simulation. For example, if the behavior model evaluation satisfies a threshold, then the behavior model may be retrained.

Processing the real-world data and the simulated world data to generate the domain gap metrics and the realism evaluation may include executing the evaluation model to generate vehicle dynamics model metrics as part of the domain gap metrics and a vehicle dynamics model evaluation as part of the realism evaluation. The vehicle dynamics model metrics may be generated by recovering the real world trajectory of the autonomous system from a replay of recorded actuation commands of the autonomous system using the vehicle dynamics model and comparing the recovered trajectories from the vehicle dynamics model to the trajectories identified from the real world. The actuation commands may be recorded from operation of the autonomous vehicle in the real-world and stored in the digital twin specification. The domain gap metrics for the vehicle dynamics model may be used to revise and retrain models that form the vehicle dynamics model. For example, the vehicle dynamics model evaluation may be an average of the differences between recovered trajectories and real-world trajectories and if the vehicle dynamics model evaluation satisfies a threshold, then one or more vehicle dynamics models may be retrained.

Processing the real-world data and the simulated world data to generate domain gap metrics and a realism evaluation may include comparing the simulated latency times of the simulated world data to recorded times from the real-world data to generate latency model metrics as part of the domain gap metrics and a latency model evaluation as part of the realism evaluation. The latency model evaluation may be used to revise and retrain models that identify the latency of the actors in the virtual world simulation. For example, if the latency model evaluation satisfies a threshold, then one or more latency models may be retrained.

Processing the real-world data and the simulated world data (from the virtual world simulation) to generate domain gap metrics and a realism evaluation may include calculating an agreement value between the real-world data and the simulated world data as part of the realism evaluation. The agreement value may be used to identify the scenario corresponding to the digital twin specification as one that is of sufficient quality to be used to train machine learning models, including the models used for simulation and the models deployed to autonomous system.

Processing the real-world data and the simulated world data to generate domain gap metrics and a realism evaluation may include comparing simulated actor trajectories from the simulated world data with real actor trajectories from the real-world data to generate behavior model metrics of the domain gap metrics. The behavior model metrics may be combined to generate the behavior model evaluation, which may be used to revise and retrain models that identify the behaviors of the actors in a world simulation. For example, if the behavior model evaluation satisfies a threshold, then one or more of the behavior models may be retrained.

Processing the real-world data and the simulated world data to generate domain gap metrics and a realism evaluation may include computing a difference in an autonomous system's state from the simulated world data and the real-world data as part of the realism evaluation. The difference may be for an executed position over time in closed loop. In other words, based off of the real data, the final position of an autonomous system in a scenario may be measured to be at a specific location. The final position of the simulated autonomous system may be at a different location in the simulated data then for the real data. The difference in the location of the autonomous system at the end of the scenario may be quantified as the difference in the autonomous system state from which to form the realism evaluation.

The method may further include presenting the real-world data and the simulated world data. The real-world data and the simulated world data may be displayed on a user interface. Presenting the real-world data and the simulated world data may include the transmission of the data from a server computing system to a client computing system. The client computing system may display the data in a visual representation to depict the differences between aspects of the real-world data and the simulated world data.

The method may include training, which may include collecting a set of digital twin specifications. Each digital twin specification may correspond to one of multiple scenarios.

The training may further include filtering the set of digital twin specifications using the realism evaluation and a realism evaluation threshold to generate a filtered set of digital twin specifications. A digital twin specification may describe a scenario and the realism evaluation associated with the digital twin specification then may be used to identify other scenarios similar to the digital twin specification to be used for training for the scenario. The better the realism evaluation (e.g., the closer to 1 in a range from 0 to 1), the higher the likelihood that the corresponding digital twin specification will be used to train the models of the system. The realism evaluation threshold may be set to a numerical value (e.g., 0.8) to separate high quality digital twin specifications from low quality digital twin specifications so that the high quality digital twin specifications may be used for training.

The training may further include training a model of a virtual driver using the filtered set of digital twin specifications to generate a trained model. The filtered set of digital twin specifications include the digital twin specifications that satisfied the realism evaluation threshold and are of high quality.

The training may further include deploying the trained model to an autonomous system. After a model is trained using the filtered set of digital twin specifications, the model may be deployed. Autonomous system models (e.g., a virtual driver) may be deployed to an autonomous system to perform autonomous driving tasks.

The training may further include training a model of the world simulation responsive to the realism evaluation and a model evaluation threshold to improve the world simulation based on the realism evaluation. Simulation models may be deployed to a world simulation to generate simulated data.

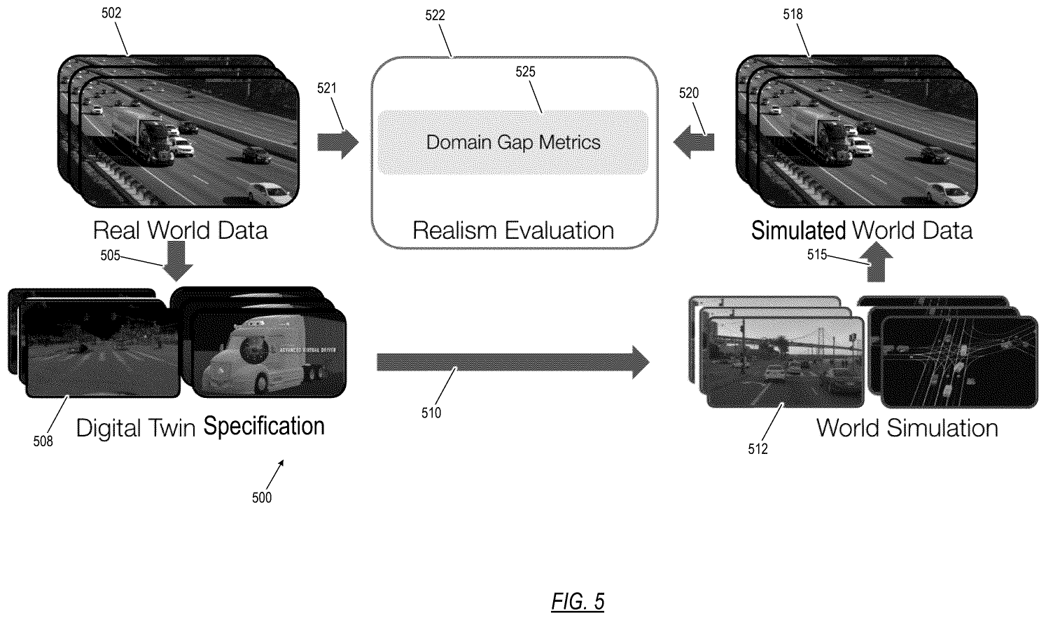

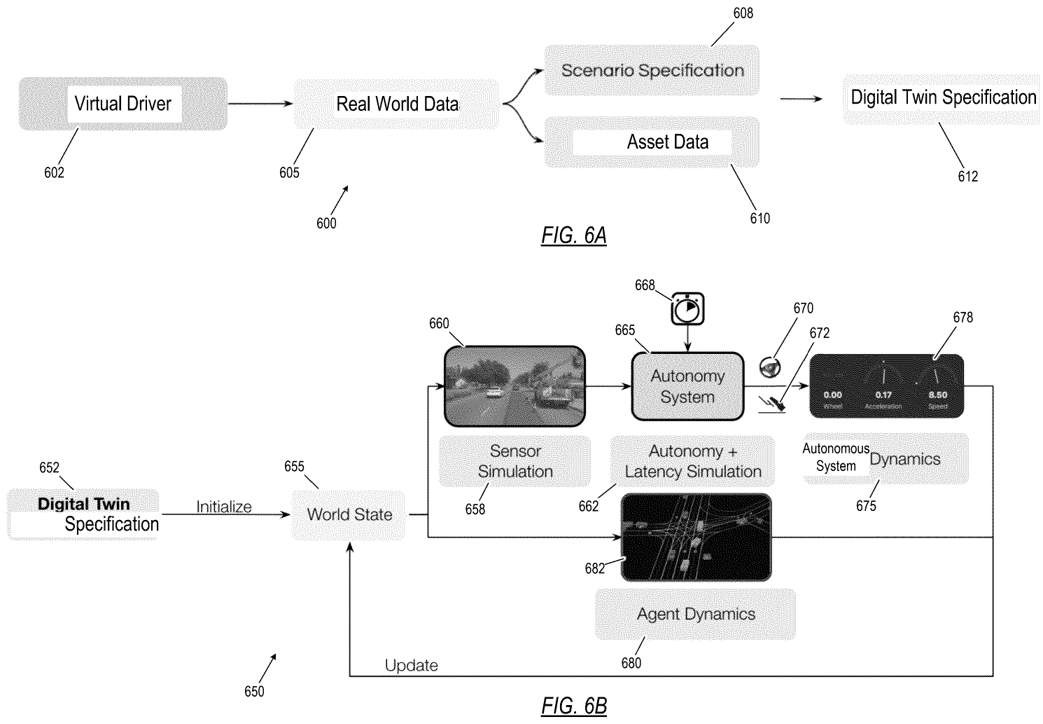

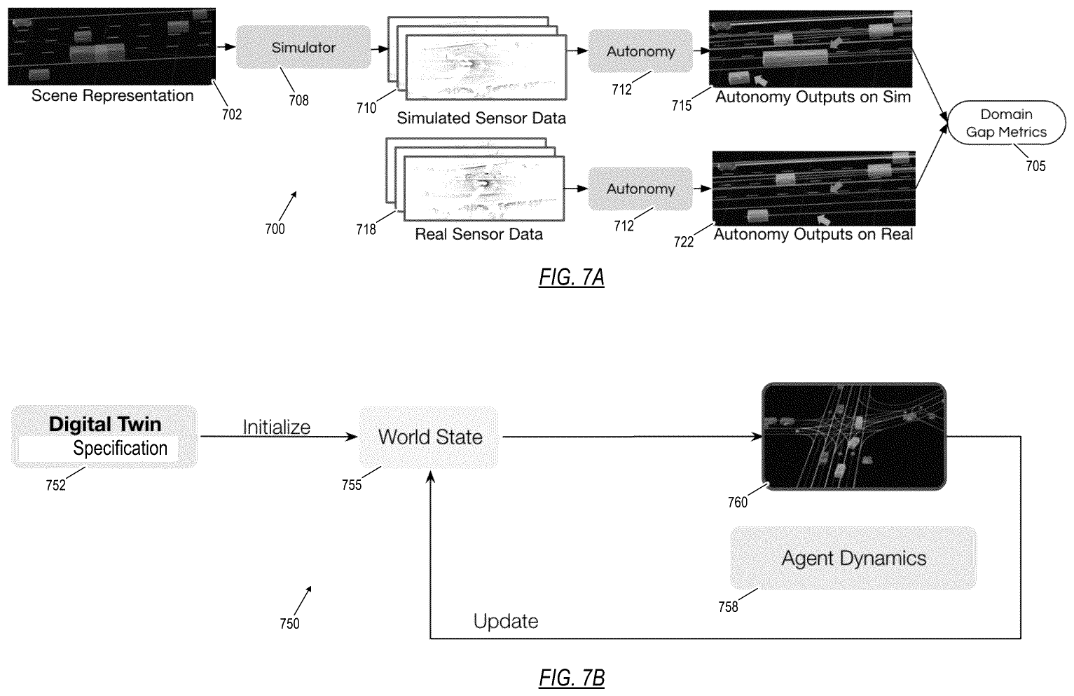

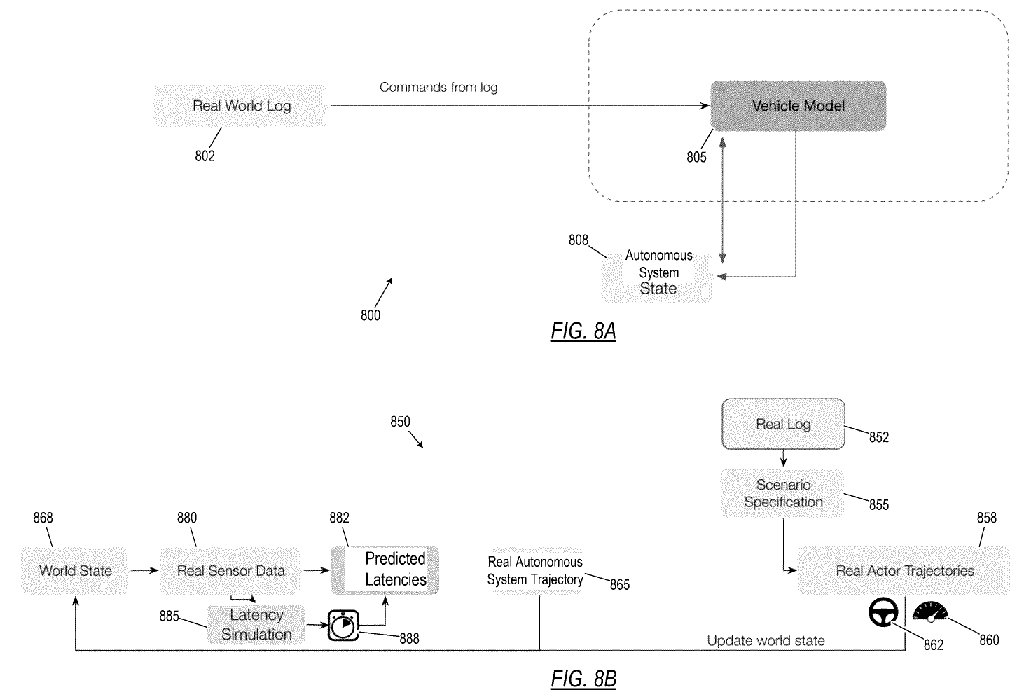

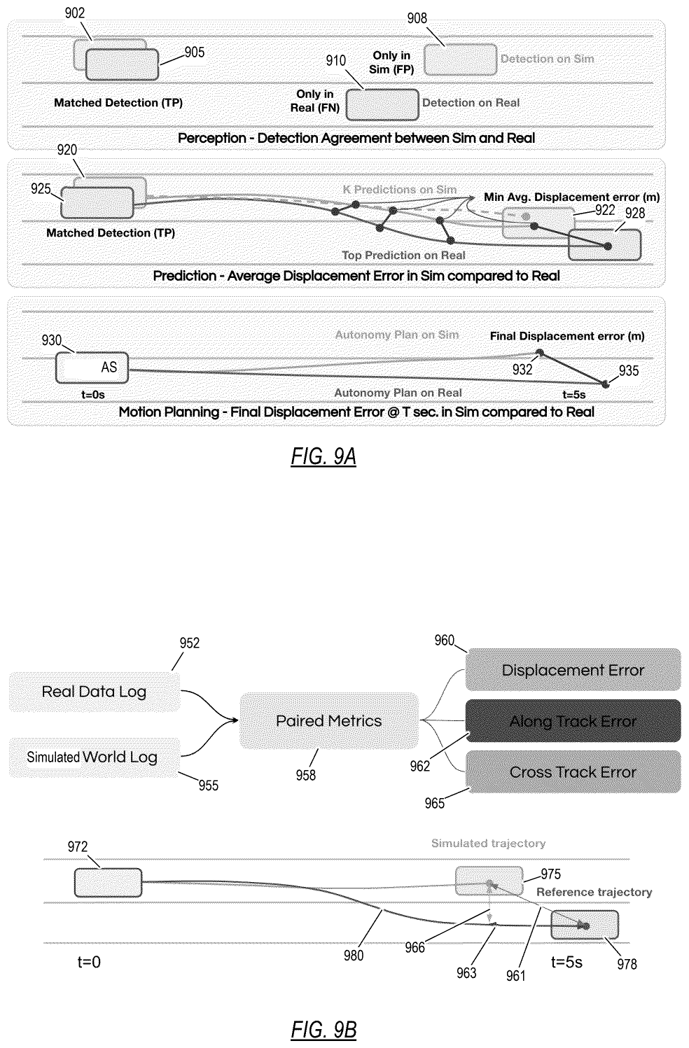

Turning to FIG. 5, the data flow (500) is depicted. The real-world data (502) is generated by autonomous systems in the real world and input to the process (505). The process (505) operates on the real-world data (502) to generate the digital twin specification (508). The digital twin specification (508) includes asset data and model data from which the simulated world data (518) may be generated using the world simulation (512). The process (510) inputs the digital twin specification (508) to the world simulation (512). The world simulation (512) processes the digital twin specification (508) to generate the simulated world data (518). The process (515) may record and store the simulated world data (518) generated from the world simulation (512). The simulated world data (518) is generated by the world simulation (512) from the digital twin specification (508). The processes (520) and (521) operate on the simulated world data (518) and the real-world data (502) to generate the realism evaluation (522) with the domain gap metrics (525).

The data flow (500) may be executed with a computing system that may be referred to as an autonomy realism evaluation of simulation (ARES) system. The system operates to evaluate the realism of a simulation system by understanding the performance of the simulation with respect to autonomy systems under test. A “paired-scenario” approach is used to evaluate (as quantified by the realism evaluation (522)) the domain gap (measured by the domain gap metrics (525)) of the world simulation (512) by reconstructing digital twins of real world scenarios, and then running the full autonomy system in closed loop in simulation and evaluating the reproduction of the real-world data in the simulated world data using the digital twin specification (508) and the world simulation (512).

An ARES system may utilize a methodology that evaluates simulation realism with respect to an autonomy system under test. The system may also be applied across multiple autonomy systems under test, giving a more robust measure of realism. First, the autonomy system is deployed to an autonomous system, such as a self-driving vehicle. Events of the autonomy system driving in the real world (e.g., the real-world data (502)) are collected and curated to a set of events to form a realism evaluation benchmark that captures the diversity of the real world. For each event, a digital twin specification (e.g., the digital twin specification (508)) is built that describes the content of the scenario. The digital twin specification (508) may include the initial conditions of the scenario, the current and past dynamic states of the autonomous system and one or more the high-level maneuvers of the actors, the platform and sensor configuration of the autonomous system, as well as representations describing the appearance of the scene and the actors. Given the digital twin specification (508) as input to the world simulation (512), the world simulation (512) generates the simulated world data (518) that may be used to evaluate the autonomy system in closed loop. For each scenario in the evaluation benchmark, the same autonomy system that was deployed in the real world may be run in simulation. Metrics (e.g., the domain gap metrics (525)) may be computed to measure the differences between how the autonomy system drives in simulation with how the autonomy system performed in the real world, which may include differences between the real-world data (502) and the simulated world data (518).

The domain gap may be measured to generate the domain gap metrics (525). Given the logs from the real-world data (502), a set of metrics are devised that quantify how different the data gathered from world simulation (512) is from the data gathered from the real world. As there are several simulation modules, such as sensor simulation, actor behaviors, and autonomous system model dynamics, metrics may be analyzed at the module-level, such as by comparing differences between the simulated sensor data and the real sensor data for the same scene, and comparing the trajectory error between actors in simulation and actors in the real world. Comparison and analysis of autonomy-level metrics may also be performed to detect differences in the actors detected in the scene for the digital twin specification (508).

System-level metrics may be computed that check whether the autonomy system performed the same maneuver in both simulation and the real world. For each timestep, the system-level metrics may be used to check whether what the autonomous system is doing in simulation for the same underlying scenario (e.g., a truck cutting in, an actor coming out of occlusion, etc.) is what the autonomous system did in the real world. Distribution metrics such as velocity and acceleration profiles of the actors may also be computed in the scene to check that simulation system and the real-world match at the aggregate level in addition to the paired setting.

Turning to FIG. 6A, the data flow (600) is depicted. The virtual driver (602) generates real-world data (605), which logs real data. Primary world data (605) is processed to generate the scenario specification (608) and the asset data (610), which are combined to form the digital twin specification (612).

As an autonomy system drives in the real world, logs of the sensor data and autonomy performance are recorded. A scenario representation may be extracted and a digital twin specification for the scenario may be built, which can subsequently be modified and used for closed loop (and open loop) simulation testing.

The digital twin specification of the scenario includes the information used by a world simulator to recreate the scenario and accurately execute the autonomy system in closed loop. The digital twin specification includes information about the vehicle platform that is driving autonomously (e.g., the make, geometry, physical parameters, engine parameters, etc.), the sensor configuration (e.g., the types of sensors, the relative firing synchronization patterns, the calibrated intrinsics and extrinsics, etc.), hardware compute, and autonomy software.

To accurately simulate the real world, a digital twin of the environment is built directly and automatically from raw sensor data (which may be part of the real-world data (605)). 3D representations of the objects and backgrounds encountered in the real world are encoded for each scenario, including the geometry and appearance. Instantiations of digital world reconstruction may be generated through neural rendering or mesh reconstruction, where 3D assets are constructed for the foreground actors and background scene. A specification of the scenario (also referred to as a scene) itself may be extracted, including an initial state (e.g., the autonomous system's state, a map of the road topology, other actor locations, etc.) and how the scenario evolves over time (e.g., each actors' high-level intention, driving style, etc.). The scenario specification may be created using machine learning (ML) models that identify objects and object trajectories based on sensor data or through human annotation.

Turning to FIG. 6B, the system (650) executes a world simulation in closed loop. The digital twin specification (652) is used to generate initial values for the world state (655). The world state (655) includes values used by the models of the world simulation to generate simulated world data. The sensor simulation model (658) processes information from the world to generate the sensor data (660), which is input to the autonomy system (665). The autonomy and latency simulation model (662) operates the autonomy system (665) to process the sensor data (660) and the latency data (668) to generate action data that includes the steering data (670) and the acceleration data (672) (including acceleration and braking information). The action data may be processed by the autonomous system dynamics model (675) to generate the autonomous system dynamics data (678), identify the steering angle, acceleration, speed, etc., of the autonomous system being operated in the world simulation by the autonomy system (665). The agent dynamics model processes information from the world state (655) to generate the agent dynamics data (682), which may identify the steering angles, accelerations, speeds, etc., for the other autonomous systems in the world simulation. The data generated by the world simulation, including the self-driving data (678) and the agent dynamics data (682) is processed by the world simulation to update the world state (655). The process continues until the scenario of the digital twin specification (652) is completed.

Closed-loop simulation may be used for evaluation. Given the digital twin specification (652) for a scenario, the autonomy system under test (e.g., the autonomy system (665)) may run in simulation in closed loop to generate simulated world data. The digital twin specification (652) initializes the world state (655) for the environment and actor locations. The sensor simulation model (658) takes the world state (655) and generates the sensor data (660) at that timestep, and the autonomy system (665) consumes the sensor data (660) and generates steering and acceleration actuation outputs (670) and (672), taking into consideration the latency data (668) of running on the actual vehicle platform. The state of the autonomous system is updated through the autonomous system dynamics model (675), and concurrently, the states of the other actors are also updated through the agent dynamics model (680). For a modular simulation system, the evaluation setting may be modified to isolate the realism evaluation to specific modules in the simulator, such as evaluating a sensor simulation system (which may include the sensor simulation model (658)), an actor behavior model, a latency model, an autonomous system dynamics model, etc., separately.

Turning to FIG. 7A, the data flow (700) generates the domain gap metrics (705). The scene representation (702) is loaded from a digital twin specification into the sensor simulation module (708). The sensor simulation module (708) processes the scene representation to generate the simulated sensor data (710). The simulated sensor data (710) may be generated from a closed-loop simulation of the sensor simulation module (708) and then recorded or may be generated by creating a scene representation for each time step of the real sensor data (718) to minimize the discrepancies between the real sensor data (718) and the simulated sensor data (710). The simulated sensor data (710) may then be input to the autonomy system (712) in an open-loop simulation to generate the autonomy outputs (715) from the simulated sensor data (710). The real sensor data (718) may be data captured from an autonomous system that is used as the basis for generating the digital twin specification from which the scene representation (702) is generated. The real sensor data (718) is input to the same autonomy system (712) in another open-loop simulation to generate the autonomy outputs (722) from real sensor data (718). The autonomy outputs (715) from the simulated sensor data (710) are compared with the autonomy output (722) from the real sensor data (718) to generate the domain gap metrics (705).

Hence, given paired simulated and real sensor data (e.g., the pair of the simulated sensor data (710) and the real sensor data (718)) for the same scenario, autonomy may be run on both the simulated and real data in open loop and the domain gap may be compared for the autonomy system (712) under test. For sensor simulation evaluation, the autonomy system may take as input a sequence of sensor data and additional information, such as a map, and generate autonomy outputs (e.g., the autonomy outputs (715) and (722)). The autonomy system (712) may be evaluated in an open-loop setting, where at each timestep a sequence of either the simulated sensor data (710) or the real sensor data (718) is provided as input. As the evaluation is open loop, the scene configuration may be the same between simulation and real at each timestep so that the sensor simulation module (708) is isolated to be the source of discrepancy. Additionally, if domain gap metrics are computed using the modular autonomy system (712) that performs perception (object detection), motion forecasting (actor trajectories), and motion planning (output planned trajectory of the SDV), realism metrics may be computed on intermediate level autonomy outputs.

Turning to FIG. 7B, the data flow (750) may be a subset of the dataflow (650) of FIG. 6B for a closed-loop simulation. The digital twin specification (752) is used to initialize the world state (755) for a world simulation. The agent dynamics model (758) processes the world state (755) to generate the agent dynamics data (760). The agent dynamics data (760) is processed by the world simulation to update the world state (755) with the actors and objects in the scene. The process may continue until the scenario identified with the digital twin specification (752) is completed.

With regard to behavior evaluation, each actor may be controlled by behavior policies executed by a behavior model and evaluated in closed loop, where the actors interact with each other. The policy that is executed is rolled out over time. An autonomous system may replay an original trajectory or also be controlled by another actor model, but autonomy does not run, and no sensor simulation or other sensor simulation modules are executed to isolate the realism evaluation to the agent dynamics model (758).

To isolate the realism of the behavior of the agents in the scene, instead of the autonomous system being controlled by an autonomy system, each of the agents, including the autonomous system, may be controlled by one or more behavior models. To perform the evaluation in a controlled manner, sensor simulation is not performed, autonomy or latency models are not run, and the autonomous system dynamics are not simulated. The simulation still runs all actor models in closed loop, allowing the scenario to evolve over time in simulation which may diverge from what happened in the real world.

Turning to FIG. 8A, the data flow (800) may be used for autonomous system dynamics metrics and evaluation. The autonomous system model (805) takes the original commands of steering and acceleration actuation inputs extracted from the real world log (802) from real-world data along with the current state of the autonomous system. With the log and state information, the autonomous system model (805) (also referred to as an autonomous system dynamics model or vehicle dynamics model) estimates an updated state that is stored to the autonomous system state (808) for each point in time in a simulation of a scenario.

To isolate the realism of the autonomous system dynamics, the recorded actuation commands of the autonomous system in the real world may be included in the digital twin specification and then replayed directly in simulation. The trajectory of the autonomous system in the real world may be compared to the trajectory of the autonomous system in the simulated world to evaluate the autonomous system model (805). For autonomous system dynamics where the actuation commands are replayed, the displacement error (calculated with the equation below) may be evaluated as the l₂ distance (e.g., the Euclidean distance) between the autonomous system location in simulation (Tt) compared the location from the original reference log (Tt) at a given point in time, averaged across the full scenario execution.

$$DisplacementError = \frac{1}{T} {\sum }_{t = 1}^{T} {ℓ}_{2} ( {\hat{T}}_{t} , {T}_{t} ) \qquad Eq . 1$$

Turning to FIG. 8B, the data flow (850) may be used for latency metrics and evaluation. The real log (852) for an autonomous system is extracted from real-world data and used to form the scenario specification (855). The scenario specification (855) is used to generate the real actor trajectories (858) (for other vehicles and systems) that may include the steering angle (862) and the acceleration value (860). The real actor trajectories (858) are inputs to the world state (868). The real autonomous system trajectory (865) is also an input to the world state (868). The world state is (868) is generated from the trajectories (865) and (858) and may be included with the real sensor data (880) as input to the latency simulation model (885). The latency simulation model (885) processes the real sensor data (880) to generate the latency data (888) and form the predicted latencies (882). An evaluation process may compare the run-time of different modules to the predicted latencies (882) to generate domain gap metrics and a realism evaluation for the latency simulation model (885).

For the latency evaluation, the original sensor data may be replayed in an open-loop evaluation setting, and the latency module predicts the run-time/delays throughout the process as if the system was running on the real autonomous system platform onboard. For the latency metrics, the realism of the latency model may be evaluated by comparing the sensor message times or execution times of different autonomy components and compare with the recorded times from the logs in the real-world data. For example, the number of cycles of autonomy execution in simulation may be computed and compared to the real log. For execution cycles that ran at the same time, end-to-end latency times may be computed.

Latency evaluation may also be processed. In the digital twin specification, the real sensor data may be included. The autonomy system may be run in open-loop log replay and have the latency simulation model (885) estimate the run time of different parts of the autonomy system, and determine if the run times match the original profiled times from the real log (852) of the real-world data.

Turning to FIG. 9A, multiple sensor simulation metrics may be generated. Given autonomy outputs on simulated and real sensor data, the agreement between the two may be computed with outputs on real sensor data being the “ground-truth.”

The sensor simulation metrics may include detection distributional agreement with delta average precision (ΔAP) and delta recall (ΔRecall). The absolute differences in autonomy performance may be measured when run on the simulated and real sensor data over the benchmark for a scenario using average precision (AP) and recall. Delta average precision may be defined as ΔAP=|ΔPᵣₑₐₗ−APₛᵢₘ| for AP, and an equivalent metric for delta recall. These definitions may be under a pre-specified intersection over union (IoU) threshold. A correct simulator would mean that the autonomy system has the same performance between the simulated and real datasets, resulting in ΔAP and ΔRecall of 0.

The sensor simulation metrics may include detection agreement (DA). An example of matched detection is shown with the detections (902) and (905). The detection (902) is from simulated data and the detection (905) is from real data. The detections (902) and (905) are within a threshold distance so that the system interprets the two detections as matching to the same object (e.g., vehicle). The detection (908) from simulated data and the detection (910) from real data do not match even though the detections may represent the same object. Distributional metrics may be limited to measuring perception performance in aggregate over the full dataset. To assess whether an actor in simulation at time m in the same frame of the paired-scenario is mis-detected or correctly detected in both the simulated and real sensor data, the detection agreement (DA) may be reported. Intuitively, the detection agreement may be a non-symmetric measure of similarity for two sets of model outputs, computed by treating one of the sets as pseudo-labels. The autonomy model outputs computed on the real sensor data are used as “labels”, and the simulated sensor data model outputs are used as the proposals. The average precision and recall may then be computed under different IoU thresholds. Detection agreement average precision (DA AP) and detection agreement recall (DA Recall) with a value of 1 mean that an autonomy system generates the same output detection set on both simulated and real sensor data.

The sensor simulation metrics may include prediction error. The displacement error (a form of prediction error) may be calculated for the object represented by the predictions (920) and (922) from simulated data by the predictions (925) and (928) from the real data. The error at each time step may be calculated and averaged to determine a minimum average replacement error. The differences between motion forecasting outputs run when the input to the autonomy system may be computed with simulated sensor data and with real sensor data. The displacement error of each actor may be used as the disagreement metric. Since prediction models are often multi-modal, to handle diverse future, the most-likely mode in the real sensor data may be used as the ground-truth, and the minimum average displacement error (minADE) may be computed between each of the trajectory modes predicted by the autonomy system when run with the simulated sensor data as input for that actor. Since different simulation methods result in different actor prediction sets, the prediction results may be evaluated a fixed detection recall.

The sensor simulation metrics may include plan discrepancy (PD). The plan discrepancy may be a final displacement error for the location of an autonomous system. The autonomous system (AS) (930) starts at the same location in both the simulated data and real data but ends at the location (932) in a simulated data and at the location (935) in the real data, from which the final placement error may be generated. Open loop planning may be performed on both real and simulated sensor data sequences and the discrepancies between planner outputs may be measured. Planning metrics are helpful in understanding the impact of sensor realism on the decision making of the autonomous system. Specifically, the [symbol] ₂error may be measured between planner waypoints at a fixed time in the future, for every log frame:

$$PlanDiscrepancy = {\sum }_{i = 1}^{N} {\sum }_{m = i}^{i + P} {‖ {T}_{m}^{( s )} - {T}_{m}^{( r )} ‖}_{2}^{2} , \qquad Eq . 2$$

where N is the length of simulation, P the planning horizon, and Tₘ denotes the plan trajectory at time m, under either real or simulated data.

Turning to FIG. 9B, behavior metrics and evaluations may be determined. The real data log (952) may be paired with the simulated world log (955) to generate the paired metrics (958). The paired metrics (958) may include the displacement error (960), the along track error (962), and the cross track error (965). Additional metrics may be included. The paired metrics (958) may be derived from the trajectories (972), (975), and (978). The trajectory (972) is the initial trajectory and may be the same in both the simulated world and real data logs (955) and (952). The trajectory (975) is the trajectory from the simulated world log (955) and the trajectory (978) is the trajectory from the real data log (952). The displacement error (960) is the distance (961) between the trajectories (975) and (978). The along track error (962) is the distance (963) “along” the track (980). The cross track error is the distance (966) perpendicular to the track (980). In the paired setting, the behavior model metrics compares the trajectory of each in simulation against the recorded one in the real log, computing the along track error (962), the cross-track (965), and displacement error (960).

Paired metrics may be used to evaluate how closely unrolled simulated actor trajectories \hat{T}^{(m)} ∈ [symbol] ^{N>2} match observations in the real data T^{(m)}∈ [symbol] ^{N×2}. A pairwise displacement error for M actors may be computed as:

$$DisplacementError = \frac{1}{m} {\sum }_{m = 1}^{m} d ( {\hat{T}}^{( m )} , {T}^{( m )} ) \qquad Eq . 3$$

In Equation 3, d is the [symbol] ₂ error computed along an actor's (x, y) coordinates at a given timestep, averaged over time. Along track error (ATE) and cross track error (CTE) may be measured by projecting the error at each time step along the ground truth longitudinal and lateral directions of the trajectory, respectively. When comparing the displacement error between different actors at a specific timestep, the relative time from when each actor was first observed may be used.

Distributional metrics may be used in addition to using paired metrics to measure realism at the per-simulation level. Distributional metrics may be used to measure aggregate behavioral realism across multiple simulations. Histogram distributions may first be computed for various actor features (e.g., speed, lateral acceleration, bumper-to-bumper distance) for actors across all observations and simulations, P and Q, respectively. Using the histograms, the Jensen-Shannon Divergence (JSD) is computed between the discrete probabilities of real and simulation data for each feature separately:

$$DistributionalRealism = \frac{1}{2} ( ( D ( P \vert \vert M ) + D ( Q \vert \vert M ) ) \qquad Eq . 4$$

where D(P∥Q) is the Kullback-Leiber (KL) divergence between two discrete distributions and

$$M = \frac{1}{2} ( P + Q )$$

is the pointwise average of each probability in P and Q.

Rule-compliance metrics may be used to evaluate compliance to traffic rules, such as by measuring collision and offroad rates. The collision rate may be measured as:

$$CollisionRate = \frac{1}{M} {\sum }_{m + 1}^{M} {c}^{( m )} \qquad Eq . 5$$

where C^{(m)} is 1 if the m-th actor's bounding box intersects with the bounding box of any other actor at any timestep in a given simulation and is 0 otherwise. Similarly, an actor may be marked as offroad if the actor's bounding box

$${ℬ}_{t}^{( m )}$$

is not entirely contained within a polygon corresponding to the annotated onroad map regions [symbol] at any timestep t,

$$OffroadRate = \frac{1}{M} {{\sum }_{m = 1}^{M}}_{t ∈ [ N ]}^{max 1} [ ⊈ ] \qquad Eq . 6$$

Both metrics may first be averaged across all actors in a given simulation, and then averaged across simulations.

Turning to FIG. 10, an autonomous system may be located at the executed positions (1022), (1025), and (1028) for the simulation execution (1020) that is paired with the real execution (1050). The real execution (1050) may identify the autonomous system to be located at the executed positions (1052), (1055), and (1058), which may diverge from the executed positions (1022), (1025), and (1028) for the simulation execution (1020).

A full system metric may be computed as the difference in the autonomous system state, such as the executed position over time in closed loop, between simulation and the real world. System level metrics that check whether the autonomy system performed the same maneuver in both simulation and the real world may be computed. Doing so ensures that at each timestep, a check of whether what the autonomy system is properly doing in simulation as was done in the real world for the same underlying scenario (e.g., a truck cutting in, an actor coming out of occlusion, etc.). Distribution metrics such as velocity and acceleration profiles of the actors in the scene may be computed to check that world simulation and the real-world data match at the aggregate level in addition to the paired setting.

Turning to FIG. 11, the user interface (1100) may display simulated data and real data that may include discrepancies. The user interface (1100) displays simulated sensor data in the view (1122) (e.g., simulated camera data) and displays simulated model outputs (e.g., trajectories) in the view (1125). The user interface (1100) displays real sensor data in the view (1152) (real camera data) and displays real model outputs (e.g., trajectories) in the view (1155). The simulated data and the real data may be for the same time step during a scenario. Actors and the autonomous system may be at different locations within the scenario between the simulated and real data. The closer the convergence of the simulated data to the real data, the higher the confidence in the models used by the world simulation to generate the simulated data.

The user interface shows the system evaluating an autonomy system driving up a hill. On the right (including the views (1152) and (1155)) is real world autonomous system sensor data and autonomy performance, the left (including the views (1122) and (1125)) is simulation. The top row (including the views (1122) and (1152)) shows simulated camera data, and the bottom row (the views (1125) and (1155)) shows simulated LiDAR and autonomy outputs (with detections and the predicted trajectories (1128) and (1158) as well as the motion plans (1130) and (1160)). In both the simulated data views (1122) and (1125) and the real data views (1152) and (1155), similar autonomous system dynamics behavior are shown as the autonomous system (a truck) drives steadily up a hill. Domain gap metrics may indicate the simulation system under test has high realism, with executed cumulative relative errors on a set nominal driving scenarios, indicating a high simulator realism. As an example, a low error may be below one percent (e.g., 0.04%) and a high realism may be above ninety nine percent (e.g., 99.96%). Other, thresholds for low and high may be used.

Embodiments may be implemented on a computing system specifically designed to achieve an improved technological result. When implemented in a computing system, the features and elements of the disclosure provide a significant technological advancement over computing systems that do not implement the features and elements of the disclosure. Any combination of mobile, desktop, server, router, switch, embedded device, or other types of hardware may be improved by including the features and elements described in the disclosure. For example, as shown in FIG. 12A, the computing system (1200) may include one or more computer processors (1202), non-persistent storage (1204), persistent storage (1206), a communication interface (1212) (e.g., Bluetooth interface, infrared interface, network interface, optical interface, etc.), and numerous other elements and functionalities that implement the features and elements of the disclosure. The computer processor(s) (1202) may be an integrated circuit for processing instructions. The computer processor(s) (1202) may be one or more cores or micro-cores of a processor. The computer processor(s) (1202) includes one or more processors. The one or more processors may include a central processing unit (CPU), a graphics processing unit (GPU), a tensor processing units (TPU), combinations thereof, etc.

The input device(s) (1210) may include a touchscreen, keyboard, mouse, microphone, touchpad, electronic pen, or any other type of input device. The input device(s) (1210) may receive inputs from a user that are responsive to data and messages presented by the output device(s) (1208). The inputs may include text input, audio input, video input, etc., which may be processed and transmitted by the computing system (1200) in accordance with the disclosure. The communication interface (1212) may include an integrated circuit for connecting the computing system (1200) to a network (not shown) (e.g., a local area network (LAN), a wide area network (WAN) such as the Internet, mobile network, or any other type of network) and/or to another device, such as another computing device.

Further, the output device(s) (1208) may include a display device, a printer, external storage, or any other output device. One or more of the output device(s) (1208) may be the same or different from the input device(s) (1210). The input (1210) and output device(s) (1208) may be locally or remotely connected to the computer processor(s) (1202). Many different types of computing systems exist, and the aforementioned input (1210) and output device(s) (1208) may take other forms. The output device(s) (1208) may display data and messages that are transmitted and received by the computing system (1200). The data and messages may include text, audio, video, etc., and include the data and messages described above in the other figures of the disclosure.

Software instructions in the form of computer readable program code to perform embodiments may be stored, in whole or in part, temporarily or permanently, on a non-transitory computer readable medium such as a CD, DVD, storage device, a diskette, a tape, flash memory, physical memory, or any other computer readable storage medium. Specifically, the software instructions may correspond to computer readable program code that, when executed by a processor(s), is configured to perform one or more embodiments, which may include transmitting, receiving, presenting, and displaying data and messages described in the other figures of the disclosure.

The computing system (1200) in FIG. 12A may be connected to or be a part of a network. For example, as shown in FIG. 12B, the network (1220) may include multiple nodes (e.g., node X (1222), node Y (1224)). Each node may correspond to a computing system, such as the computing system (1200) shown in FIG. 12A, or a group of nodes combined may correspond to the computing system (1200) shown in FIG. 12A. By way of an example, embodiments may be implemented on a node of a distributed system that is connected to other nodes. By way of another example, embodiments may be implemented on a distributed computing system having multiple nodes, where each portion may be located on a different node within the distributed computing system. Further, one or more elements of the aforementioned computing system (1200) may be located at a remote location and connected to the other elements over a network.

The nodes (e.g., node X (1222), node Y (1224)) in the network (1220) may be configured to provide services for a client device (1226), including receiving requests and transmitting responses to the client device (1226). For example, the nodes may be part of a cloud computing system. The client device (1226) may be a computing system, such as the computing system (1200) shown in FIG. 12A. Further, the client device (1226) may include and/or perform all or a portion of one or more embodiments.

The computing system (1200) of FIG. 12A may include functionality to present raw and/or processed data, such as results of comparisons and other processing. For example, presenting data may be accomplished through various presenting methods. Specifically, data may be presented by being displayed in a user interface, transmitted to a different computing system, and stored. The user interface may include a GUI that displays information on a display device. The GUI may include various GUI widgets that organize what data is shown as well as how data is presented to a user. Furthermore, the GUI may present data directly to the user, e.g., data presented as actual data values through text, or rendered by the computing device into a visual representation of the data, such as through visualizing a data model.

As used herein, the term “connected to” contemplates multiple meanings. A connection may be direct or indirect (e.g., through another component or network). A connection may be wired or wireless. A connection may be a temporary, permanent, or a semi-permanent communication channel between two entities.

The various descriptions of the figures may be combined and may include or be included within the features described in the other figures of the application. The various elements, systems, components, and steps shown in the figures may be omitted, repeated, combined, and/or altered as shown from the figures. Accordingly, the scope of the present disclosure should not be considered limited to the specific arrangements shown in the figures.

In the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as by the use of the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Further, unless expressly stated otherwise, “or” is an inclusive “or” and, as such includes “and.” Further, items joined by an “or” may include any combination of the items with any number of each item unless expressly stated otherwise.

In the above description, numerous specific details are set forth in order to provide a more thorough understanding of the disclosure. However, it will be apparent to one of ordinary skill in the art that the technology may be practiced without these specific details. In other instances, well-known features have not been described in detail to avoid unnecessarily complicating the description. Further, other embodiments not explicitly described above can be devised which do not depart from the scope of the claims as disclosed herein. Accordingly, the scope should be limited only by the attached claims.

What is claimed is:

1. A method comprising:
receiving real-world data comprising real sensor data captured with a sensor system of an autonomous system;
generating a digital twin specification from the real-world data;
executing a world simulation using the digital twin specification to generate simulated world data; and
processing the real-world data and the simulated world data using an evaluation model to generate a domain gap metric and a realism evaluation,
wherein the domain gap metric comprises a difference measured between the real-world data and the simulated world data, and
wherein the realism evaluation comprises one or more of:
an error value from the domain gap metric, and
a realism value of one or more components of the world simulation, wherein the realism value is calculated as one minus the error value.

2. The method of claim 1, wherein receiving real-world data comprises:
recording real logs and real model output as part of the real-world data.

3. The method of claim 1, wherein executing the world simulation comprises:
executing the world simulation in closed loop using an autonomous system model.

4. The method of claim 1, wherein processing the real-world data and the simulated world data to generate the domain gap metrics and the realism evaluation comprises:
executing the world simulation in open loop using an autonomous system model with the real sensor data to generate first simulated model output from the real sensor data;
executing the world simulation in open loop using the autonomous system model with simulated sensor data to generate second simulated model output from the simulated sensor data; and
executing the evaluation model using the first simulated model output and the second simulated model output to generate a sensor simulation evaluation as part of the realism evaluation.

5. The method of claim 1, wherein processing the real-world data and the simulated world data to generate the domain gap metrics and the realism evaluation comprises:
executing the evaluation model using simulated behavior model output to generate behavior model metrics as part of the domain gap metrics and a behavior model evaluation as part of the realism evaluation for a behavior model.

6. The method of claim 1, wherein processing the real-world data and the simulated world data to generate the domain gap metrics and the realism evaluation comprises:
executing the evaluation model to generate vehicle dynamics model metrics as part of the domain gap metrics and a vehicle dynamics model evaluation as part of the realism evaluation.

7. The method of claim 1,
wherein executing the world simulation comprises:
executing the world simulation in open loop using the real-world data with a latency model to generate simulated latency times as part of the simulated world data, and
wherein processing the real-world data and the simulated world data to generate the domain gap metrics and the realism evaluation comprises:
comparing the simulated latency times of the simulated world data to recorded times from the real-world data to generate latency model metrics as part of the domain gap metrics and a latency model evaluation as part of the realism evaluation.

8. The method of claim 1, wherein processing the real-world data and the simulated world data to generate the domain gap metrics and the realism evaluation comprises:
calculating an agreement value between the real-world data and the simulated world data as part of the realism evaluation.

9. The method of claim 1, wherein processing the real-world data and the simulated world data to generate the domain gap metrics and the realism evaluation comprises:
comparing simulated actor trajectories from the simulated world data with real actor trajectories from the real-world data to generate behavior model metrics of the domain gap metrics.

10. The method of claim 1, wherein processing the real-world data and the simulated world data to generate the domain gap metrics and the realism evaluation comprises:
computing a difference in an autonomous system state from the simulated world data and the real-world data as part of the realism evaluation, wherein the difference is for an executed position over time in closed loop.

11. The method of claim 1, further comprising:
presenting the real-world data and the simulated world data, wherein the real-world data and the simulated world data are displayed on a user interface.

12. The method of claim 1, wherein generating the digital twin specification comprises:
executing a twin generator using the real-world data to generate real asset data and real model data as part of the digital twin specification.

13. The method of claim 1, further comprising:
collecting a set of digital twin specifications comprising the digital twin specification;
filtering the set of digital twin specifications using the realism evaluation and a realism evaluation threshold to generate a filtered set of digital twin specifications;
training a model of a virtual driver using the filtered set of digital twin specifications to generate a trained model; and
deploying the trained model to an autonomous system.

14. The method of claim 1, further comprising:
training a model of the world simulation responsive to the realism evaluation and a model evaluation threshold.

15. A system comprising:
at least one processor; and
an application that, when executing on the at least one processor, performs operations comprising:
receiving real-world data comprising real sensor data captured with a sensor system of an autonomous system,
generating a digital twin specification from the real-world data,
executing a world simulation using the digital twin specification to generate simulated world data, and
processing the real-world data and the simulated world data using an evaluation model to generate a domain gap metric and a realism evaluation,
wherein the domain gap metric comprises a difference measured between the real-world data and the simulated world data, and
wherein the realism evaluation comprises one or more of:
an error value from the domain gap metric, and
a realism value of one or more components of the world simulation, wherein the realism value is calculated as one minus the error value.

16. The system of claim 15, wherein receiving real-world data comprises:
recording real logs and real model output as part of the real-world data.

17. The system of claim 15, wherein executing the world simulation comprises:
executing the world simulation in closed loop using an autonomous system model.

18. The system of claim 15, wherein processing the real-world data and the simulated world data to generate the domain gap metrics and the realism evaluation comprises:
executing the world simulation in open loop using an autonomous system model with the real sensor data to generate first simulated model output from the real sensor data;
executing the world simulation in open loop using the autonomous system model with simulated sensor data to generate second simulated model output from the simulated sensor data; and
executing the evaluation model using the first simulated model output and the second simulated model output to generate a sensor simulation evaluation as part of the realism evaluation.

19. The system of claim 15, wherein processing the real-world data and the simulated world data to generate the domain gap metrics and the realism evaluation comprises:
executing the evaluation model using simulated behavior model output to generate behavior model metrics as part of the domain gap metrics and a behavior model evaluation as part of the realism evaluation for a behavior model.

20. A non-transitory computer readable medium comprising instructions executable by at least one processor to perform operations comprising:
receiving real-world data comprising real sensor data captured with a sensor system of an autonomous system;
generating a digital twin specification from the real-world data;
executing a world simulation using the digital twin specification to generate simulated world data; and
processing the real-world data and the simulated world data using an evaluation model to generate a domain gap metric and a realism evaluation,
wherein the domain gap metric comprises a difference measured between the real-world data and the simulated world data, and
wherein the realism evaluation comprises one or more of:
an error value from the domain gap metric, and
a realism value of one or more components of the world simulation, wherein the realism value is calculated as one minus the error value.
